(19) United States
(12) Patent Application Publication
(10) Pub. No.: US 2024/0051079 A1
(43) Pub. Date: Feb. 15, 2024

(54) CHEMICAL MECHANICAL POLISHING APPARATUS AND CHEMICAL MECHANICAL POLISHING SYSTEM USING THE SAME

(71) Applicant: SAMSUNG ELECTRONICS CO., LTD., SUWON-SI (KR)

(72) Inventors: Eunkyoung Kim, Suwon-si (KR); Kiho Bae, Suwon-si (KR); Hoyoung Kim, Suwon-si (KR); Boumyoung Park, Suwon-si (KR); Boun Yoon, Suwon-si (KR)

(21) Appl. No.: 18/296,021

(22) Filed: Apr. 5, 2023

(30) Foreign Application Priority Data
Aug. 12, 2022 (KR) 10-2022-0101170

(51) Int. Cl. B24B 37/005; G05D 11/13

(52) U.S. Cl. CPC B24B 37/0056; G05D 11/138; H01L 21/31053

(57) ABSTRACT

A chemical mechanical polishing apparatus includes: supply pipes to which a slurry stock solution and a diluent are supplied; flow rate control units, respectively disposed on the supply pipes to control flow rates of the slurry stock solution and the diluent; a mixer connected to the flow rate control units and configured to mix the slurry stock solution and the diluent, supplied from the supply pipes, to prepare a slurry; a slurry storage unit connected to the mixer and configured to store the slurry prepared in the mixer; a slurry supply unit configured to draw out the slurry stored in the slurry storage unit and to supply the slurry to a polishing pad; and a control unit configured to control the flow rate control units to control a mixing ratio of the slurry stock solution and the diluent and a flow rate of the slurry to the polishing pad.

### CROSS-REFERENCE TO RELATED APPLICATION(S)

This application claims priority under 35 U.S.C. § 119 to Korean Patent Application No. 10-2022-0101170 filed on Aug. 12, 2022, in the Korean Intellectual Property Office, the disclosure of which is incorporated by reference herein in its entirety.

### TECHNICAL FIELD

The present disclosure relates to a chemical mechanical polishing apparatus and a chemical mechanical polishing method using the same.

### DISCUSSION OF RELATED ART

A chemical mechanical polishing (CMP) process is a process of planarizing a surface of a substrate by combining a mechanical polishing effect using an abrasive with a chemical reaction effect using an acid or a base solution.

Such a CMP process is used to planarize various materials in a process of polishing a silicon oxide layer for the purpose of forming an interlayer dielectric (ILD) or a shallow trench isolation (STI) feature, a tungsten plug, a copper interconnection, or the like.

### SUMMARY

Example embodiments provide a chemical mechanical polishing apparatus for varying a mixing ratio of a slurry depending on process conditions and a chemical mechanical polishing using the same.

According to an example embodiment of the present disclosure, a chemical mechanical polishing apparatus includes: a hydrogen peroxide storage tank configured to supply a hydrogen peroxide; a deionized (DI) water storage tank configured to supply DI water; an additive storage tank configured to supply an additive; a plurality of flow rate control units configured to control a flow rate of the hydrogen peroxide, the DI water, and the additive; a mixer connected to the plurality of flow rate control units and configured to mix a slurry stock solution, the hydrogen peroxide, the DI water, and the additive with each other to prepare a slurry having a predetermined flow rate; a slurry storage unit configured to store the slurry prepared in the mixer; a slurry supply unit configured to draw out the slurry stored in the slurry storage unit and to supply the slurry to a polishing pad; and a control unit configured to control the plurality of flow rate control units to control a mixing ratio of the slurry stock solution, the hydrogen peroxide, the DI water, and the additive and to control the predetermined flow rate according to a chemical mechanical polishing process performed using the polishing pad.

According to an example embodiment of the present disclosure, a chemical mechanical polishing apparatus includes: a plurality of supply pipes to which a slurry stock solution and a diluent are supplied; a plurality of flow rate control units, respectively disposed on the supply pipes to control flow rates of the slurry stock solution and the diluent; a mixer connected to the flow rate control units and configured to mix the slurry stock solution and the diluent, supplied from the supply pipes, with each other to prepare slurry; a slurry storage unit connected to the mixer and configured to store the slurry prepared in the mixer; a slurry supply unit configured to draw out the slurry stored in the slurry storage unit and to supply the slurry to a polishing pad; and a control unit configured to control the flow rate control units to control a mixing ratio of the slurry stock solution and the diluent and a flow rate of the slurry to the polishing pad.

According to an example embodiment of the present disclosure, a chemical mechanical polishing system includes: a slurry stock solution supply device configured to supply a slurry stock solution; a supply line connected to the slurry stock solution supply device to transfer the slurry stock solution; and a chemical mechanical polishing apparatus connected to the supply line to receive the slurry stock solution and configured to dilute the slurry stock solution to prepare a slurry and to perform a chemical mechanical polishing process using the slurry. The chemical mechanical polishing apparatus includes: a hydrogen peroxide storage tank configured to supply a hydrogen peroxide; a deionized (DI) water storage tank configured to supply a DI water; an additive storage tank configured to supply an additive; a first supply pipe connected to the supply line to be supplied with the slurry stock solution; a second supply pipe connected to the hydrogen peroxide storage tank to be supplied with the hydrogen peroxide; a third supply pipe connected to the DI water storage tank to be supplied with the DI water; a fourth supply pipe connected to the additive storage tank to be supplied with the additive; a first flow rate control unit, a second flow rate control unit, a third flow rate control unit, and a fourth flow rate control unit, respectively disposed on the first supply pipe, the second supply pipe, the third supply pipe, and the fourth supply pipe; a mixer connected to the first flow rate control unit, the second flow rate control unit, the third flow rate control unit, and the fourth flow rate control unit and configured to mix the slurry stock solution, the hydrogen peroxide, the DI water, and the additive, respectively supplied from the first supply pipe, the second supply pipe, the third supply pipe, and the fourth supply pipe, with each other to prepare the slurry at a predetermined flow rate; a slurry storage unit connected to the mixer and configured to store the slurry prepared in the mixer; a slurry supply unit configured to draw out the slurry stored in the slurry storage unit and to supply the slurry to a polishing pad configured to perform a chemical mechanical polishing process; and a control unit configured to control the first flow rate control unit, the second flow rate control unit, the third flow rate control unit, and the fourth flow rate control unit to control a mixing ratio of the slurry stock solution, the hydrogen peroxide, the DI water, and the additive and to control the predetermined flow rate to be a flow rate according to the chemical mechanical polishing process performed using the polishing pad.

According to an example embodiment of the present disclosure, a chemical mechanical polishing method includes: determining a flow rate of a slurry to be prepared using mixing ratio data of slurry; calculating a flow rate of a slurry stock solution for preparing the slurry and a flow rate of a diluent, using the flow rate of the slurry; using the flow rate of the slurry stock solution and the flow rate of the diluent to control a supply of the slurry stock solution and the diluent to a mixer; mixing, by the mixer, the slurry stock solution and the diluent with each other to prepare the slurry; and supplying the slurry to a polishing pad to chemically and mechanically polish a semiconductor substrate.

### BRIEF DESCRIPTION OF THE DRAWINGS

The above and other aspects, features, and advantages of the present disclosure will be more clearly understood from the following detailed description, taken in conjunction with the accompanying drawings.

FIG. 1 is a schematic diagram of a chemical mechanical polishing system according to an example embodiment of the present disclosure.

FIG. 2 is a block diagram of a chemical mechanical polishing apparatus included in the chemical mechanical polishing system of FIG. 1.

FIG. 3 is a schematic diagram of the chemical mechanical polishing apparatus included in the chemical mechanical polishing system of FIG. 1.

FIG. 4 is a schematic diagram of a chemical mechanical polishing system according to an example embodiment of the present disclosure.

FIG. 5 is a schematic diagram of a chemical mechanical polishing system according to an example embodiment of the present disclosure.

FIG. 6 is a block diagram of a chemical mechanical polishing method according to an example embodiment of the present disclosure.

### DETAILED DESCRIPTION

Hereinafter, example embodiments of the present disclosure will be described with reference to the accompanying drawings.

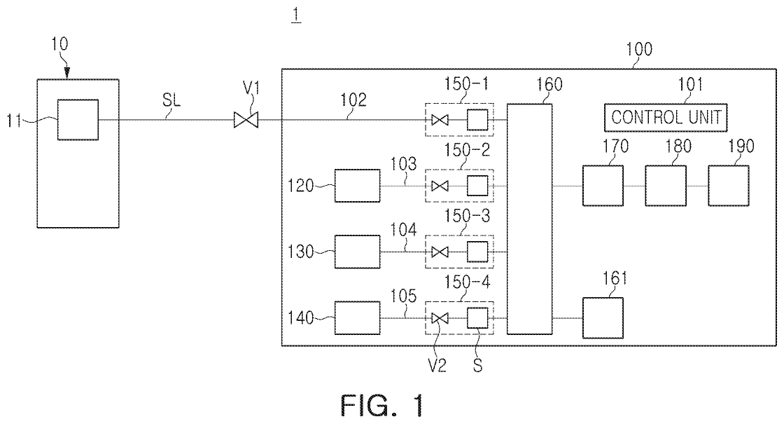

FIG. 1 is a schematic diagram of a first chemical mechanical polishing system 1 according to an example embodiment of the present disclosure.

Referring to FIG. 1, the first chemical mechanical polishing system 1 may include a slurry stock solution supply device 10 supplying a slurry stock solution, a chemical mechanical polishing apparatus 100 generating slurry using the slurry stock solution supplied from the slurry stock solution supply device 10 and performing a chemical mechanical polishing process using the generated slurry. A supply line SL may connect the slurry stock solution supply device 10 and the chemical mechanical polishing apparatus 100 to each other. The first chemical mechanical polishing system 1 according to an example embodiment of the present disclosure is illustrated as having a structure in which a single chemical mechanical polishing apparatus may be connected to a single slurry stock solution supply device. Example embodiments of the present disclosure are not limited thereto and the number of chemical mechanical polishing apparatuses connected to a single slurry stock solution supply device may be varied according to example embodiments of the present disclosure. For example, in the first chemical mechanical polishing system 1, a plurality of chemical mechanical polishing apparatuses may be connected to a single slurry stock solution supply device.

The slurry stock solution supply device 10 may supply the slurry stock solution to the chemical mechanical polishing apparatus 100. The slurry stock solution supply device 10 may include a slurry stock solution storage tank 11. The slurry stock solution storage tank 11 may store the slurry stock solution. The slurry stock solution supply device 10 may be disposed separate from the chemical mechanical polishing apparatus 100. The slurry stock solution supply device 10 may supply the slurry stock solution to the chemical mechanical polishing apparatus 100 through the supply line SL. A valve V1 for controlling a flow rate of the slurry stock solution supplied through the supply line SL may be disposed on the supply line SL.

According to example embodiments of the present disclosure, a supply pump may be used for pressurizing the slurry stock solution. The supply pump may be disposed on the supply line SL.

The slurry stock solution may be used to prepare slurry for use in a chemical mechanical polishing process performed by the chemical mechanical polishing apparatus 100. The slurry may be obtained by diluting the slurry stock solution, and it should be appreciated that a diluent may be mixed with the slurry stock solution. The diluent may include an oxidizer, deionized water (DI water), and an additive. The oxidizer may be, for example, hydrogen peroxide water.

The oxidizer may be provided to control an oxidizing power of the slurry, and may be added such that a pH of the slurry may be maintained in a specific range to satisfy process conditions of a chemical mechanical polishing process to be performed. In some aspects, the oxidizer may tend to decrease in concentration with the lapse of time due to an intrinsic instability of the oxidizer. Accordingly, the oxidizing power of the slurry prepared by mixing the diluent may decrease with the lapse of time, so that the slurry may have a useful lifetime in which the oxidizing power of the slurry satisfies the process conditions. An unused portion of the slurry may be discarded after a predetermined time has passed, for example, after the useful lifetime to ensure that the process conditions may be satisfied.

The first chemical mechanical polishing system 1 according to an example embodiment of the present disclosure may be configured such that a process of mixing the diluent with the slurry stock solution may be performed in the chemical mechanical polishing apparatus 100, thereby reducing a time until the slurry is used in the chemical mechanical polishing process.

Hereinafter, the chemical mechanical polishing apparatus 100 will be described with reference to FIGS. 1 to 3.

The chemical mechanical polishing apparatus 10 may include a mixer 160 mixing a diluent with a slurry stock solution supplied from the slurry stock solution supply device 10 to prepare slurry, a slurry storage unit 170 storing the slurry generated in the mixer 160, and a slurry supply unit 180 supplying the slurry stored in the slurry storage unit 170 to the polishing pad 192. A control unit 101 of the chemical mechanical polishing apparatus 10 may control the mixer 160, the slurry storage unit 170, and the slurry supply unit 180 of the chemical mechanical polishing apparatus 10. The control unit 101 may control the slurry stock solution supply device 10. According to example embodiments of the present disclosure, the chemical mechanical polishing apparatus 100 may further include a cleaning solution supply unit 161. For example, the diluent may include an oxidizer, deionized (DI) water, and an additive, and the oxidizer may be hydrogen peroxide. Example embodiments of the present disclosure are not limited thereto, and the type of the diluent may vary depending on process conditions of a chemical mechanical polishing process. In addition, the chemical mechanical polishing apparatus 100 may have a storage tank supplying the diluent therein. For example, the chemical mechanical polishing apparatus 100 may include a hydrogen peroxide storage tank 120, a DI water storage tank 130, and an additive storage tank 140 therein. The hydrogen peroxide storage tank 120, the DI water storage tank 130, and the additive storage tank 140 may have sizes sufficient to be disposed in the chemical mechanical polishing apparatus 100.

The mixer 160 may mix a diluent with the slurry stock solution, supplied from the slurry stock solution supply device 10, to prepare slurry. The mixer 160 may supply the prepared slurry to the slurry storage unit 170. In an example embodiment of the present disclosure, the number of mixers may correspond to the number of platens 190 on which the chemical mechanical polishing process is performed. In addition, in an example embodiment of the present disclosure, one or more mixers may supply slurry to two or more slurry storage units. In this case, the mixer 160 may sequentially supply the slurry to the two or more slurry storage units, including slurry storage unit 170. The mixer 160 may have a size allowing the mixer 160 to be disposed in the chemical mechanical polishing apparatus 100, and may have an internal space sufficient to generate an amount of slurry sufficient to perform a polishing process for one a semiconductor substrate. The mixer 160 may have an internal space sufficient to generate an amount of slurry sufficient to perform a polishing process for one or more semiconductor substrates.

The mixer 160 may be connected to a first supply pipe 102, a second supply pipe 103, a third supply pipe 104, and a fourth supply pipe 105, to which a slurry stock solution, a hydrogen peroxide solution, DI water, and an additive may be respectively supplied, to receive the slurry stock solution, the hydrogen peroxide solution, the DI water, and the additive. The first supply pipe 102 may be connected to a supply line SL, and the second supply pipe 103 may be connected to a hydrogen peroxide storage tank 120. The third supply pipe 104 may be connected to a DI water storage tank 130, and the fourth supply pipe 105 may be connected to an additive storage tank 140.

A first flow rate control unit 150-1, a second flow rate control unit 150-2, a third flow rate control unit 150-3, and a fourth flow rate control unit 150-4 may be connected to the first supply pipe 102, the second supply pipe 103, the third supply pipe 104, and the fourth supply pipe 105 to control flow rates, respectively. Each of the first flow rate control unit 150-1, the second flow rate control unit 150-2, the third flow rate control unit 150-3, and the fourth flow rate control unit 150-4 may have a valve V2 and a flow meter S. An operation of the valve V2 may be controlled by the control unit 101. A flow rate may be measured by the flow meter S. The measured flow rate may be transmitted to the control unit 101. Accordingly, the control unit 101 may control the first flow rate control unit 150-1, the second flow rate control unit 150-2, the third flow rate control unit 150-3, and the fourth flow rate control unit 150-4 to control the flow rates of the slurry stock solution, the hydrogen peroxide solution, the DI water, and the additives introduced into the mixer 160.

In addition, the control unit 101 may control the first flow rate control unit 150-1, the second flow rate control unit 150-2, the third flow rate control unit 150-3, and the fourth flow rate control unit 150-4 such that a flow rate of the slurry, prepared in the mixer 160, may be the same as a predetermined flow rate. The control unit 101 may control the first flow rate control unit 150-1, the second flow rate control unit 150-2, the third flow rate control unit 150-3, and the fourth flow rate control unit 150-4 using a database including slurry mixing ratio data. The slurry mixing ratio data may be data storing a slurry mixing ratio for a polishing process of each semiconductor substrate, and may be established as a database. According to example embodiments of the present disclosure, the database may be stored in the control unit 101. Accordingly, the control unit 101 may prepare slurry at a slurry mixing ratio appropriate for each semiconductor substrate on which the polishing process is performed using the polishing pad 192 based on the slurry mixing ratio data. The control unit 101 may prepare the slurry such that a flow rate of the prepared slurry is sufficient to perform a current polishing process. For example, the control unit 101 may prepare the slurry such that the flow rate of the prepared slurry is sufficient to perform one polishing process. Accordingly, in the mixer 160, slurry having a mixing ratio appropriate for each semiconductor substrate may be prepared, and the slurry may be prepared only at a flow rate to perform the polishing process of each semiconductor substrate once. As a result, in some example embodiments of the present disclosure, an amount of slurry may be prepared corresponding to the number of semiconductor substrates on which the polishing process is performed in the chemical mechanical polishing apparatus 100, so that the slurry may be prevented from being prepared in an unnecessarily large amount.

The slurry storage unit 170 may store the slurry prepared in the mixer 160. The slurry storage unit 170 may provide the stored slurry to the slurry supply unit 180. The slurry supply unit 180 may have an internal space sufficient to store the slurry prepared in the mixer 160. According to example embodiments of the present disclosure, an outlet 172 for draining the slurry may be formed in the slurry storage unit 170.

According to example embodiments of the present disclosure, a pH sensor 171 for measuring pH of the stored slurry may be disposed in the slurry storage unit 170. The pH sensor 171 may measure the pH of the slurry. The pH sensor 171 may transmit a measured value of the pH of the slurry to the control unit 101. When the pH of the slurry measured by the pH sensor 171 is outside of a reference range, the control unit 101 may open the outlet 172 to drain the slurry stored in the slurry storage unit 170.

The slurry supply unit 180 may supply the slurry, supplied from the slurry storage unit 170, to the polishing pad 192 attached to the platen 190.

The cleaning solution supply unit 161 may be connected to the mixer 160 to supply a cleaning solution to the mixer 160. The cleaning solution supply unit 161 may supply a cleaning solution to the mixer 160 clean slurry remaining in the mixer 160 after a process. For example, the inside of the mixer 160 may be cleaned between chemical mechanical polishing processes. In at least one example, the inside of the mixer 160 may be cleaned between two processes using slurries having different mixing ratios.

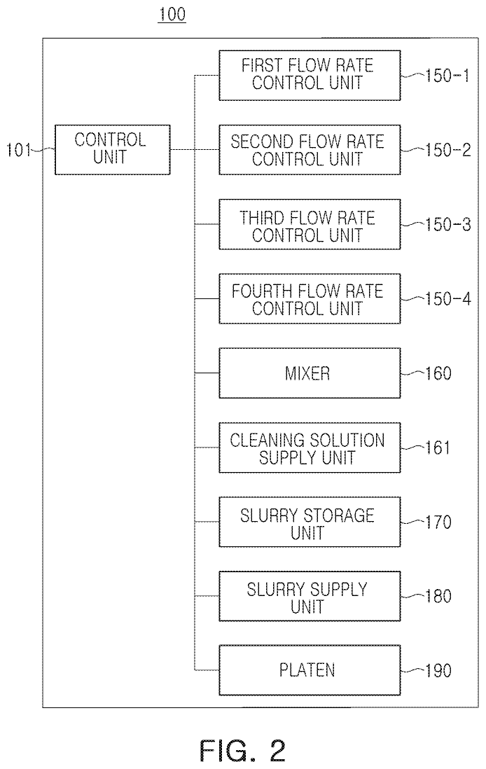

Referring to FIG. 2, the control unit 101 may control an overall operation of the chemical mechanical polishing apparatus 100. For example, the control unit 101 may be implemented as a processor such as a central processing unit (CPU), a graphics processing unit (GPU), a microprocessor, an application specific integrated circuit (ASIC), a field programmable gate arrays (FPGA), or the like. The control unit 101 may include a memory storing various types of data used for an operation of the chemical mechanical polishing apparatus 100. A database including the slurry mixing ratio data may be stored in the memory in advance.

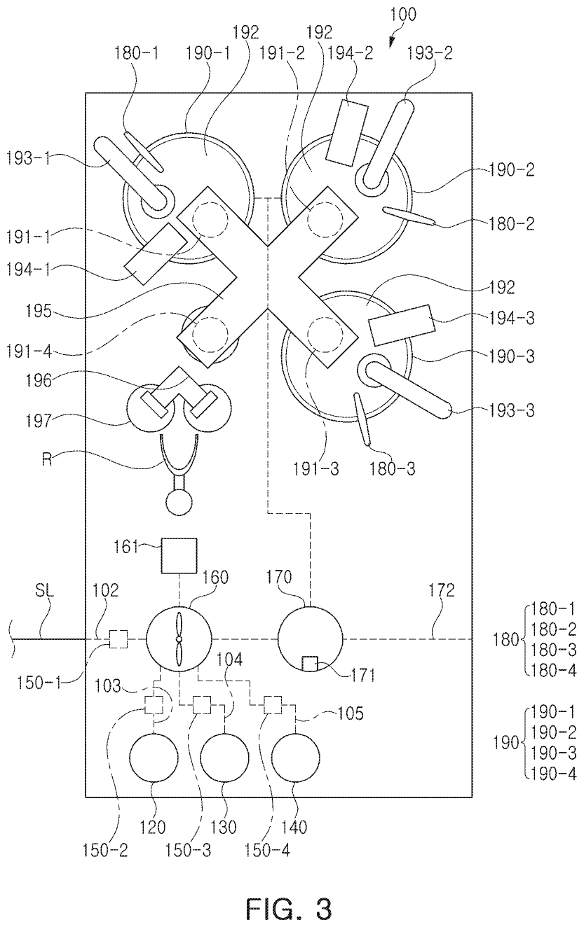

Referring to FIGS. 1 and 3, a platen 190 to which a polishing pad 192 is attached may be disposed on the slurry supply unit 180, and the slurry supply unit 180 may supply the slurry to the polishing pad 192.

FIG. 3 is a detailed schematic diagram of the chemical mechanical polishing apparatus 100 according to an example embodiment of the present disclosure. Referring to FIG. 3, the chemical mechanical polishing apparatus 100 according to an example embodiment of the present disclosure may include first platen 190-1, second platen 190-2, and third platen 190-3, first polishing head 191-1, second polishing head 191-2, third polishing head 191-3, and fourth polishing head 191-4, and first slurry supply unit 180-1, second slurry supply unit 180-2, and third slurry supply unit 180-3. The chemical mechanical polishing apparatus 10 may further include a rotatable multi-head carousel 195, a first conditioner 193-1, a second conditioner 193-2, and a third conditioner 193-3, a semiconductor substrate inverting unit 197, a loading/unloading unit 196, and a robot R.

A polishing pad 192 may be mounted to each of the first platen 190-1, the second platen 190-2, and the third platen 190-3. The first polishing head 191-1, the second polishing head 191-2, and the third polishing head 191-3 and the first slurry supply unit 180-1, the second slurry supply unit 180-2, and the third slurry supply unit 180-3 may be disposed on the first platen 190-1, the second platen 190-2, and the third platen 190-3, respectively.

The first polishing head 191-1, the second polishing head 191-2, the third polishing head 191-3, and the fourth polishing head 191-4 may be attached to the rotatable multi-head carousel 195 to move upwardly from the first platen 190-1, the second platen 190-2, and the third platen 190-3 and the loading/unloading unit 196. The first polishing head 191-1, the second polishing head 191-2, the third polishing head 191-3, and the fourth polishing head 191-4 may be configured to independently perform a lifting operation and a rotation operation. The semiconductor substrate inverting unit 197 may invert and transfer the semiconductor substrate to the loading/unloading unit 196 to polish the semiconductor substrate. The semiconductor substrate inverting unit 197 may invert and transport the semiconductor substrate from the loading/unloading unit 196. The robot R may transfer the semiconductor substrate to be polished to the semiconductor substrate inverting unit 197. The robot R may unload the polished semiconductor substrate from the semiconductor substrate inverting unit 197. The first conditioner 193-1, the second conditioner 193-2, and the third conditioner 193-3 may control a state of the polishing pad 192, for example, to maintain a constant polishing rate.

In the above-configured first chemical mechanical polishing system 1, slurry may be prevented from being unnecessarily prepared and a mixing ratio of the slurry may be varied depending on process conditions.

In the related art, slurry to be supplied to a chemical mechanical polishing apparatus was prepared by diluting a stock solution of the slurry in a slurry supply device disposed in an additional space, spaced apart from the chemical mechanical polishing apparatus, and the prepared slurry was supplied to the chemical mechanical polishing apparatus through a supply line. As described above, the chemical mechanical polishing apparatus received and used the prepared slurry, so that a mixing ratio of the slurry could not be varied depending on process conditions of the chemical mechanical polishing apparatus. In addition, any portion of the prepared slurry which was not used within a certain period of time would be discarded due to an oxidizer mixed during preparation of the prepared slurry. In addition, characteristics of the prepared slurry frequently changed while transferring the prepared slurry through the supply line.

The chemical mechanical polishing apparatus 100 included in the first chemical mechanical polishing system 1 according to an example embodiment of the present disclosure may include a tank in which chemicals mixed with the slurry stock solution are stored, and a mixer mixing a slurry stock solution and the chemicals with each other, and thus slurry may be prepared inside the chemical mechanical polishing apparatus 100. Accordingly, a mixing ratio of the slurry may be varied depending on process conditions of the chemical mechanical polishing apparatus 100. In some example embodiments of the present disclosure, the mixing ratio of the slurry may be varied for a single semiconductor substrate. In addition, since the chemical mechanical polishing apparatus according to an example embodiment of the present disclosure may prepare slurry in an amount sufficient to perform a polishing process on a single semiconductor substrate, and the slurry may be prevented from being prepared in an unnecessarily large amount. In an example embodiment of the present disclosure, slurry may be prepared in an amount sufficient to perform a polishing process on a single semiconductor substrate, and thus the slurry may be prevented from being deteriorated over time in a case where the slurry is prepared as a batch in advance of a polishing process.

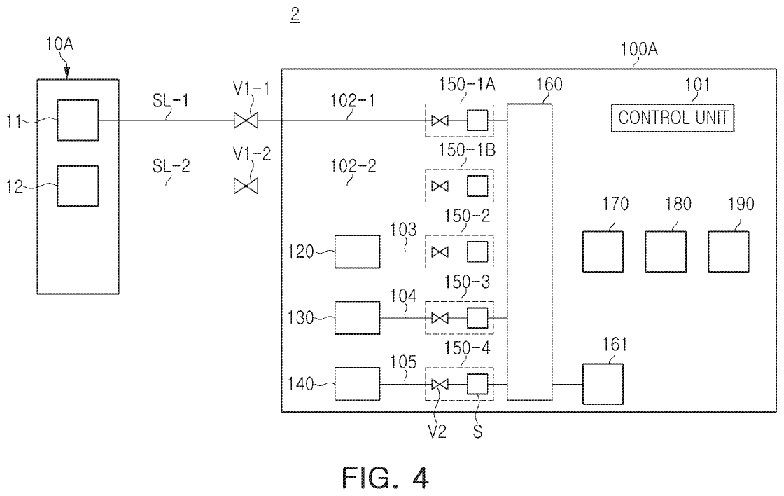

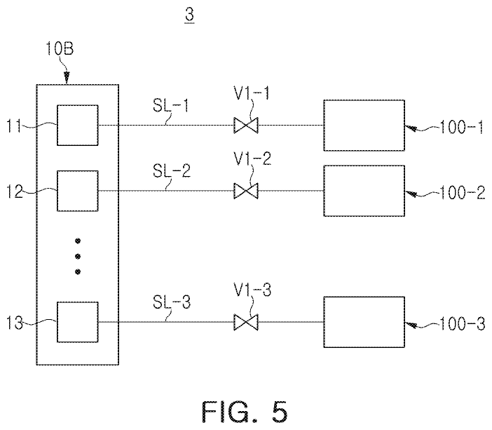

A modified example of a chemical mechanical polishing system according to example embodiments of the present disclosure will be described with reference to FIGS. 4 and 5.

FIG. 4 is a schematic diagram of a second chemical mechanical polishing system 2 according to an example embodiment of the present disclosure. The second chemical mechanical polishing system 2 of FIG. 4 may include a single mixer, such as mixer 160, a first slurry stock solution supply tank 11 and a second slurry stock solution supply tank 12. The other components may be the same as those of the first chemical mechanical polishing system 1, and thus detailed descriptions thereof will be omitted.

Referring to FIG. 4, the second chemical mechanical polishing system 2 according to an example embodiment of the present disclosure may include a slurry stock solution supply device 10A and a chemical mechanical polishing apparatus 100A. The slurry stock solution supply device 10A may include the first slurry stock solution supply tank 11 and the second slurry stock solution supply tank 12. Slurry stock solutions having different compositions may be stored in the first slurry stock solution supply tank 11 and the second slurry stock solution supply tank 12, respectively. The first slurry stock solution supply tank 11 and the second slurry stock solution supply tank 12 may be configured to supply slurries to the mixer 160 through a first supply line SL-1 and a second supply line SL-2, respectively. Valves V1-1 and V1-2 may be disposed on the first supply line SL-1 and the second supply line SL-2 to control flow rates of the slurry stock solutions supplied through the first supply line SL-1 and the second supply line SL-2, respectively. First supply pipe 102-1 and second supply pipe 102-2 may be connected to the first supply line SL-1 and the second supply line SL-2, respectively. The first supply pipe 102-1 and the second supply pipe 102-2 may be connected to the mixer 160. Accordingly, the second chemical mechanical polishing system 2 according to an example embodiment of the present disclosure may change a type of slurry supplied to the mixer 160 depending on process conditions.

FIG. 5 is a schematic diagram of a third chemical mechanical polishing system 3 according to an example embodiment of the present disclosure. The third chemical mechanical polishing system 3 of FIG. 5 may include a plurality of chemical mechanical polishing apparatuses connected to a single slurry stock solution supply apparatus 10. For ease of description, the first slurry stock solution supply tank 11, the second slurry stock solution supply tank 12, and a third slurry stock solution supply tank 13, three supply lines SL-1, SL-2, and SL-3, and three chemical mechanical polishing apparatuses 100-1, 100-2, and 100-3 are illustrated in FIG. 5. Valves V1-1, V1-2, and V1-3 may be disposed on the three supply lines SL-1, SL-2, and SL-3 to control flow rates of slurry stock solutions, respectively. The other components may be the same as those of the first chemical mechanical polishing system 1 according to an example embodiment of the present disclosure, and thus detailed descriptions thereof will be omitted.

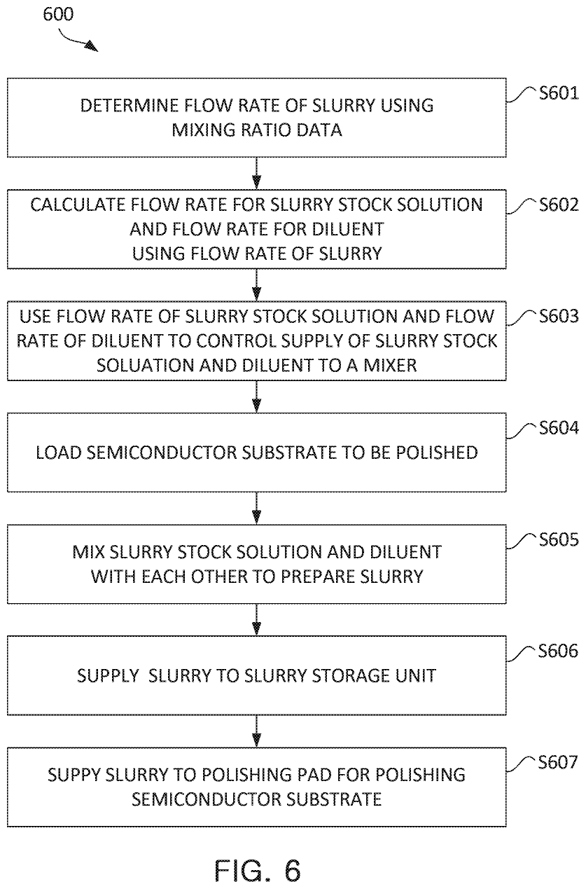

Hereinafter, a chemical mechanical polishing method 600 according to an example embodiment of the present disclosure will be described with reference to FIG. 6. The chemical mechanical polishing method according to an example embodiment of the present disclosure may be performed using the first chemical mechanical polishing system 1 of FIG. 3. A chemical mechanical polishing apparatus 100 included in the first chemical mechanical polishing system 1 will be described with reference to FIGS. 1 and 3. The first chemical mechanical polishing system 1 of FIG. 1 and the chemical mechanical polishing apparatus 100 of FIG. 3 have been described above, and thus a detailed description thereof will be omitted.

At block S601, the control unit 101 may determine a flow rate of slurry to be prepared using a database including a slurry mixing ratio data.

At block S602, the control unit 101 may calculate flow rates of a slurry stock solution, a hydrogen peroxide solution, deionized (DI) water, and an additive for preparing the slurry having the flow rate determined using the database including the slurry mixing ration data.

At block S603, the control unit 101 may control the first flow rate control unit 150-1, the second flow rate control unit 150-2, the third flow rate control unit 150-3, and the fourth flow rate control unit 150-4 based on the calculated flow rates to control flow rates of the slurry stock solution, the hydrogen peroxide solution, the DI water, and the additive, respectively.

At block S604, the control unit 101 may load a semiconductor substrate to be polished on one of the first platens 190-1, the second platen 190-2, and the third platen 190-3.

At block S605, the mixer 160 may mix the supplied slurry stock solution, hydrogen peroxide solution, DI water, and additive with each other to prepare a slurry.

At block S606, the mixer 160 may supply the prepared slurry to the slurry storage unit 170. In this case, pH of the slurry may be measured using a pH sensor 171, and the pH of the slurry measured by the pH sensor 171 may be transmitted to the control unit 101.

At block S607, the prepared slurry may be supplied to the polishing pad 192 attached to the platen 190 through the slurry supply unit 180, and a chemical mechanical polishing process may be performed.

As described above, a chemical mechanical polishing apparatus for varying a mixing ratio of slurry depending on process conditions and a chemical mechanical polishing system using the same may be provided. For example, the process conditions may define conditions for manufacturing an interlayer dielectric (ILD) or a shallow trench isolation (STI) feature, a tungsten plug, a copper interconnection, or the like. Process conditions may be predetermined for other manufacturing processes. Further, process conditions during a single process may be monitoring and varied, for example, based on the measured pH of a slurry.

While example embodiments of the present disclosure have been shown and described above, it will be apparent to those skilled in the art that modifications and variations could be made without departing from the scope of the present disclosure as defined by the appended claims.

1. A chemical mechanical polishing apparatus comprising:
a hydrogen peroxide storage tank configured to supply a hydrogen peroxide;
a deionized (DI) water storage tank configured to supply DI water;
an additive storage tank configured to supply an additive;
a plurality of flow rate control units configured to control a flow rate of the hydrogen peroxide, the DI water, and the additive;
a mixer connected to the plurality of flow rate control units and configured to mix a slurry stock solution, the hydrogen peroxide, the DI water, and the additive with each other to prepare a slurry having a predetermined flow rate;
a slurry storage unit configured to store the slurry prepared in the mixer;
a slurry supply unit configured to draw out the slurry stored in the slurry storage unit and to supply the slurry to a polishing pad; and
a control unit configured to control the plurality of flow rate control units to control a mixing ratio of the slurry stock solution, the hydrogen peroxide, the DI water, and the additive and to control the predetermined flow rate according to a chemical mechanical polishing process performed using the polishing pad.

2. The chemical mechanical polishing apparatus of claim 1, wherein a first supply line is configured to supply the slurry stock solution from a slurry stock solution supply device disposed outside the chemical mechanical polishing apparatus to the mixer.

3. The chemical mechanical polishing apparatus of claim 2, further comprising a first flow rate control unit of the plurality of flow rate control units on the first supply line and configured to control a flow rate of the slurry stock solution.

4. The chemical mechanical polishing apparatus of claim 2, wherein
the slurry stock solution supply device further comprises at least one slurry stock solution storage tank in which the slurry stock solution is stored, and
the first supply line is connected to the slurry stock solution storage tank.

5. The chemical mechanical polishing apparatus of claim 4, wherein
the slurry stock solution storage tank comprises a plurality of slurry stock solution storage tanks,
the first supply line comprises a plurality of supply lines, respectively connected to the plurality of slurry stock solution storage tanks, and
the plurality of slurry solution storage tanks are configured to store slurry stock solutions, including the slurry stock solution, having different compositions.

6. The chemical mechanical polishing apparatus of claim 1, further comprising:
a cleaning solution supply unit configured to supply a cleaning solution to the mixer to perform cleaning,
wherein the control unit controls the cleaning solution supply units to perform cleaning after the slurry prepared in the mixer is supplied to the slurry storage unit.

7. The chemical mechanical polishing apparatus of claim 1, wherein
each of the flow rate control units of the plurality of flow rate control units further comprises a valve and a flow meter.

8. The chemical mechanical polishing apparatus of claim 1, wherein the mixer further comprises a pH sensor configured to measure pH of the slurry.

9. The chemical mechanical polishing apparatus of claim 8, wherein
the control unit is configured to drain the slurry, stored in the slurry storage unit, when the pH of the slurry measured by pH sensor is outside of a reference range.

10. A chemical mechanical polishing apparatus comprising:
a plurality of supply pipes to which a slurry stock solution and a diluent are supplied;
a plurality of flow rate control units, respectively disposed on the supply pipes to control flow rates of the slurry stock solution and the diluent;
a mixer connected to the flow rate control units and configured to mix the slurry stock solution and the diluent, supplied from the supply pipes, with each other to prepare a slurry;
a slurry storage unit connected to the mixer and configured to store the slurry prepared in the mixer;
a slurry supply unit configured to draw out the slurry stored in the slurry storage unit and to supply the slurry to a polishing pad; and
a control unit configured to control the flow rate control units to control a mixing ratio of the slurry stock solution and the diluent and a flow rate of the slurry to the polishing pad.

11. The chemical mechanical polishing apparatus of claim 10, wherein
the control unit controls the flow rate control units based on a database including slurry mixing ratio data applied to respective semiconductor substrates on which a chemical mechanical polishing process is performed using the polishing pad.

12. The chemical mechanical polishing apparatus of claim 10, wherein
the diluent includes a hydrogen peroxide, a deionized (DI) water, and an additive.

13. The chemical mechanical polishing apparatus of claim 12, further comprising:
a hydrogen peroxide storage tank configured to supply the hydrogen peroxide;
a DI water storage tank configured to supply the DI water; and
an additive storage tank configured to supply the additive.

14. The chemical mechanical polishing apparatus of claim 13, wherein
the supply pipes comprise a first supply pipe, a second supply pipe, a third supply pipe, and a fourth supply pipe,
wherein the first supply pipe is connected to a supply line to which the slurry stock solution is supplied from a slurry stock solution supply device disposed outside the chemical mechanical polishing apparatus,
the second supply pipe is connected to the hydrogen peroxide storage tank,
the third supply pipe is connected to the DI water storage tank, and
the fourth supply pipe is connected to the additive storage tank.

15. The chemical mechanical polishing apparatus of claim 10, wherein
each of the flow rate control units further comprises a valve and a flow meter.

16. The chemical mechanical polishing apparatus of claim 10, wherein
the mixer further comprises a pH sensor configured to measure a pH of the slurry, and
the control unit is configured to drain the slurry, stored in the slurry storage unit, when the pH of the slurry measured by the pH sensor is outside of a reference range.

17. A chemical mechanical polishing system comprising:
a slurry stock solution supply device configured to supply a slurry stock solution;
a supply line connected to the slurry stock solution supply device to transfer the slurry stock solution; and
a chemical mechanical polishing apparatus connected to the supply line to receive the slurry stock solution and configured to dilute the slurry stock solution to prepare a slurry and to perform a chemical mechanical polishing process using the slurry,
wherein
the chemical mechanical polishing apparatus comprises:
a hydrogen peroxide storage tank configured to supply a hydrogen peroxide;
a deionized (DI) water storage tank configured to supply a DI water;
an additive storage tank configured to supply an additive;
a first supply pipe connected to the supply line to be supplied with the slurry stock solution;
a second supply pipe connected to the hydrogen peroxide storage tank to be supplied with the hydrogen peroxide;
a third supply pipe connected to the DI water storage tank to be supplied with the DI water;
a fourth supply pipe connected to the additive storage tank to be supplied with the additive;
a first flow rate control unit, a second flow rate control unit, a third flow rate control unit, and a fourth flow rate control unit, respectively disposed on the first supply pipe, the second supply pipe, the third supply pipe, and the fourth supply pipe;
a mixer connected to the first flow rate control unit, the second flow rate control unit, the third flow rate control unit, and the fourth flow rate control unit and configured to mix the slurry stock solution, the hydrogen peroxide, the DI water, and the additive, respectively supplied from the first supply pipe, the second supply pipe, the third supply pipe, and the fourth supply pipe, with each other to prepare the slurry at a predetermined flow rate;
a slurry storage unit connected to the mixer and configured to store the slurry prepared in the mixer;
a slurry supply unit configured to draw out the slurry stored in the slurry storage unit and to supply the slurry to a polishing pad configured to perform a chemical mechanical polishing process; and
a control unit configured to control the first flow rate control unit, the second flow rate control unit, the third flow rate control unit and the fourth flow rate control unit to control a mixing ratio of the slurry stock solution, the hydrogen peroxide, the DI water, and the additive and to control the predetermined flow rate to be a flow rate according to the chemical mechanical polishing process performed using the polishing pad.

18. The chemical mechanical polishing system of claim 17, wherein
the control unit controls the first flow rate control unit, the second flow rate control unit, the third flow rate control unit, and the fourth flow rate control unit based on a database including slurry mixing ratio data applied to respective semiconductor substrates on which the chemical mechanical polishing process is performed using the polishing pad.

19. The chemical mechanical polishing system of claim 17, wherein
each of the first flow rate control unit, the second flow rate control unit, the third flow rate control unit, and the fourth flow rate control unit further comprises a valve and a flow meter.

20. The chemical mechanical polishing system of claim 17, wherein
the mixer further comprises a pH sensor configured to measure a pH of the slurry.

21. (canceled)
